(19) United States
(12) Patent Application Publication
(10) Pub. No.: US 2014/0340826 A1
(43) Pub. Date: Nov. 20, 2014

(54) CONVENIENT PORTABLE INPUT DEVICE

(71) Applicant: Asia Vital Components Co., Ltd., New Taipei City (TW)

(72) Inventors: Ching-Hang Shen, New Taipei City (TW); Fu-Kuei Chang, New Taipei City (TW)

(21) Appl. No.: 13/896,332

(22) Filed: May 17, 2013

(51) Int. Cl. G06F 1/16; H05K 1/02

(52) U.S. Cl. CPC G06F 1/1666; H05K 1/028
USPC 361/679.15

(57) ABSTRACT

A portable input device includes a flexible main body, a sensing electrode layer, a protection layer and a memory metal body. The flexible main body has a first face and a second face. The sensing electrode layer has a first sensing electrode and a second sensing electrode disposed on the second face of the flexible main body. The protection layer is correspondingly disposed on the second face of the flexible main body to cover the sensing electrode layer. The memory metal body is disposed on one face of the flexible main body or one face of the protection layer for curling the flexible main body for easy carry or storage. Accordingly, the convenient portable input device is flexible, lightweight and thin for a user to conveniently carry.

### BACKGROUND OF THE INVENTION

1. Field of the Invention

The present invention relates generally to a convenient portable input device, which is convenient to carry and use.

2. Description of the Related Art

In recent years, following the development of touch panel technique, various portable electronic devices with display function, such as intelligent cellular phones, tablets and MP5, have employed touch panels instead of the conventional mechanical keys that occupy much room.

There is a trend that tablets, intelligent cellular phones and portable electronic devices or televisions are designed with handwriting and touch input functions. A user can conveniently use his/her finger or a stylus to touch and operate an electronic device. However, the intelligent cellular phone or the tablet or the portable electronic device has a relatively small screen. It is inconvenient to input data by means of handwriting. Therefore, some manufacturers have reverted to develop the earlier portable mini-keyboard and/or slim keyboard with mechanical keys. The mini-keyboard and/or slim keyboard is wiredly connected to the intelligent cellular phone, the tablet or the portable electronic device via USB or wirelessly connected to the intelligent cellular phone, the tablet or the portable electronic device via a Bluetooth device for use. This can achieve the object of convenient input. However, the mini-keyboard and/or slim keyboard still occupy a considerable space and are inconvenient to carry.

Some manufacturers have developed knockdown and foldable keyboards. However, such keyboards are like the mini-keyboard and inconvenient for a user to carry.

### SUMMARY OF THE INVENTION

It is therefore a primary object of the present invention to provide a convenient portable input device, which is convenient to carry and use.

To achieve the above and other objects, the portable input device of the present invention includes a flexible main body, a sensing electrode layer, a protection layer and a memory metal body.

The flexible main body has a first face and a second face. The sensing electrode layer has a first sensing electrode and a second sensing electrode. The first and second sensing electrodes are arranged in alignment with each other without contacting each other. The sensing electrode layer is disposed on the second face of the flexible main body. The protection layer is correspondingly disposed on the second face of the flexible main body to cover the sensing electrode layer. The memory metal body is disposed on one face of the flexible main body or one face of the protection layer for curling the flexible main body for easy carry or storage.

The convenient portable input device of the present invention is convenient to carry and operate.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a perspective exploded view of a first embodiment of the convenient portable input device of the present invention;

FIG. 2 is a perspective assembled view of the first embodiment of the convenient portable input device of the present invention;

FIG. 3 is another perspective assembled view of the first embodiment of the convenient portable input device of the present invention;

FIG. 4 is a perspective view of a second embodiment of the convenient portable input device of the present invention;

FIG. 5 is another perspective view of the second embodiment of the convenient portable input device of the present invention;

FIG. 6 is a perspective view of a third embodiment of the convenient portable input device of the present invention;

FIG. 7 is a sectional view of a fourth embodiment of the convenient portable input device of the present invention;

FIG. 8 is a perspective view of a fifth embodiment of the convenient portable input device of the present invention;

FIG. 9 is a perspective view of a sixth embodiment of the convenient portable input device of the present invention;

FIG. 10 shows that the convenient portable input device of the present invention is curled;

FIG. 11 shows that the convenient portable input device of the present invention is curled;

FIG. 12 is a perspective view of a seventh embodiment of the convenient portable input device of the present invention; and

FIG. 13 is a perspective view of an eighth embodiment of the convenient portable input device of the present invention.

### DETAILED DESCRIPTION OF THE PREFERRED EMBODIMENTS

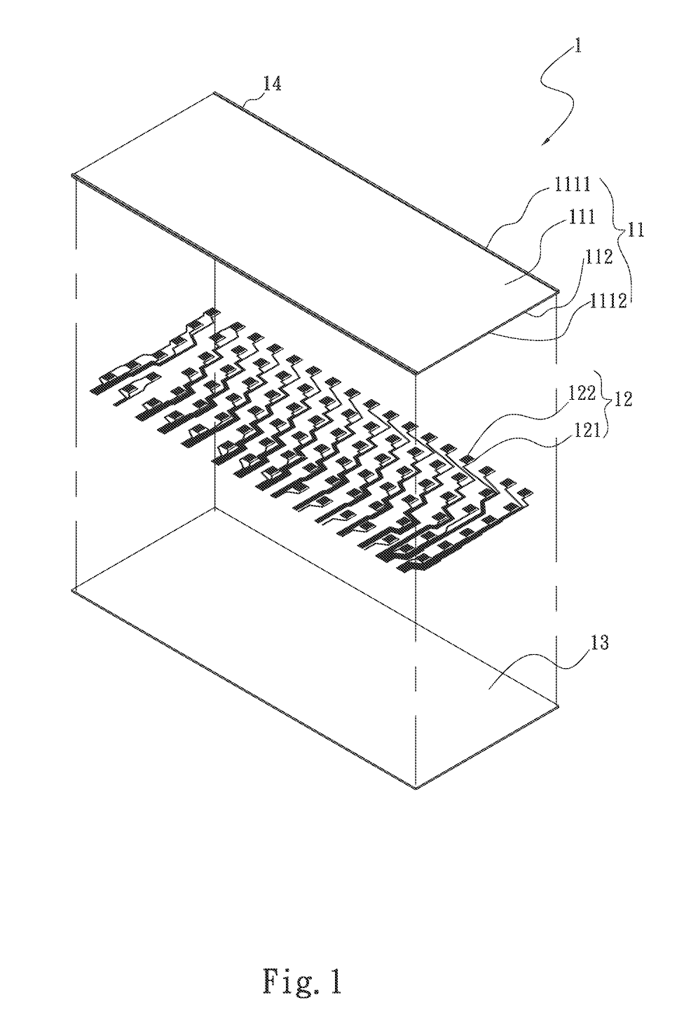

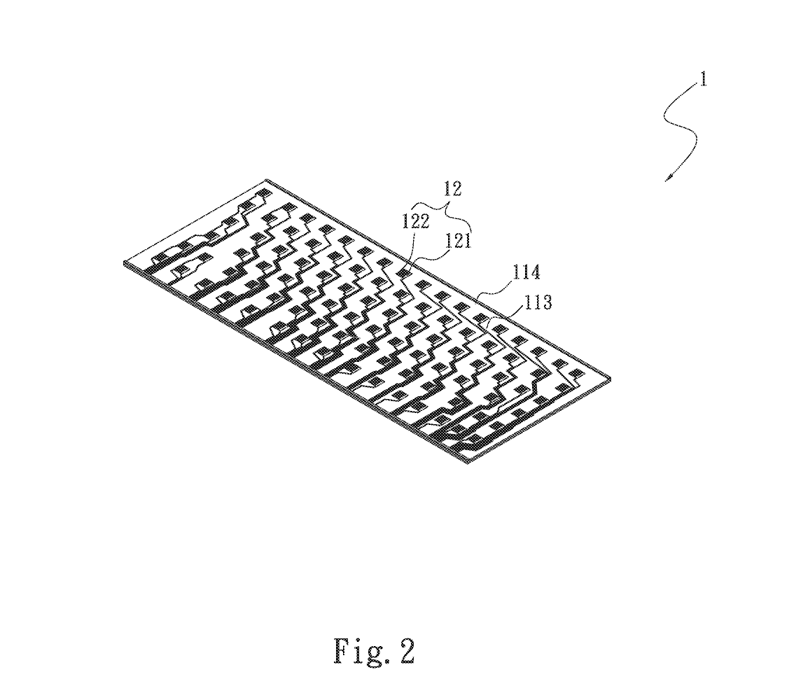

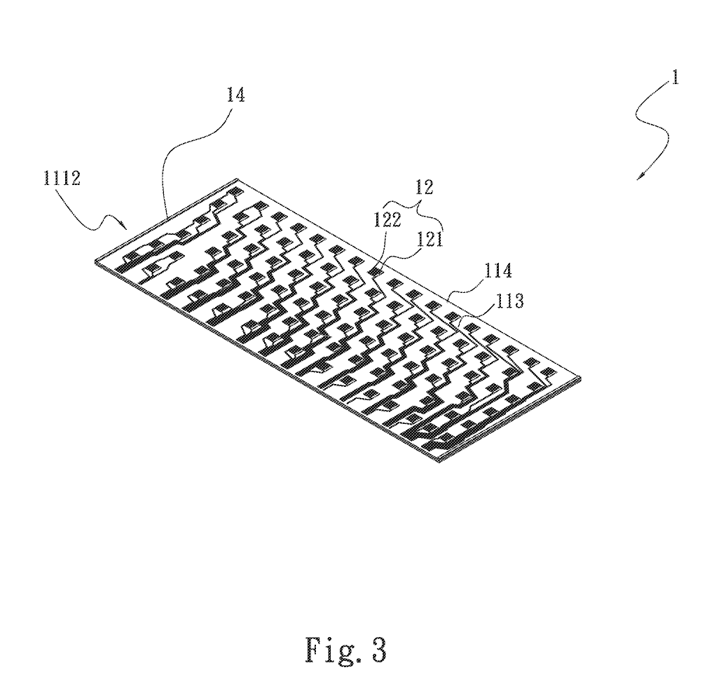

Please refer to FIGS. 1, 2 and 3. FIG. 1 is a perspective exploded view of a first embodiment of the convenient portable input device of the present invention. FIG. 2 is a perspective assembled view of the first embodiment of the convenient portable input device of the present invention. FIG. 3 is another perspective assembled view of the first embodiment of the convenient portable input device of the present invention. According to the first embodiment, the convenient portable input device 1 of the present invention includes a flexible main body 11, a sensing electrode layer 12, a protection layer 13 and a memory metal body 14.

The flexible main body 11 has a first face 111, a second face 112, a long side 1111 and a short side 1112. The sensing electrode layer 12 is selected from a group consisting of transparent ITO, nano silver and metal paste. The sensing electrode layer 12 has a first sensing electrode 121 and a second sensing electrode 122. The first and second sensing electrodes 121, 122 are arranged in alignment with each other without contacting each other. The sensing electrode layer 12 is disposed on the second face 112 of the flexible main body 11. The protection layer 13 is correspondingly disposed on the second face 112 of the flexible main body 11 to cover the sensing electrode layer 12. The memory metal body 14 is disposed on one face of the flexible main body 11 or one face of the protection layer 13. The memory metal body 14 can have the form of a wire disposed along the long side 1111 of the flexible main body 11 in parallel to the long side 1111 or disposed along the short side 1112 of the flexible main body 11 in parallel to the short side 1112 (as shown in FIG. 3). In this embodiment, the memory metal body 14 is, but not limited to, disposed on the first face 111 of the flexible main body 11 in parallel to the long side 1111 of the flexible main body 11. The memory metal body 14 is selected from a group consisting of iron-based alloy, nickel-titanium alloy, copper-based alloy, zinc and aluminum.

The flexible main body 11 is defined with a touch section 113 and a non-touch section 114 arranged around the touch section 113. The first and second sensing electrodes 121, 122 of the sensing electrode layer 12 are disposed in the touch section 113. The first and second sensing electrodes 121, 122 partially extend to the non-touch section 114. The first and second sensing electrodes 121, 122 are arranged in alignment with each other without contacting or overlapping each other.

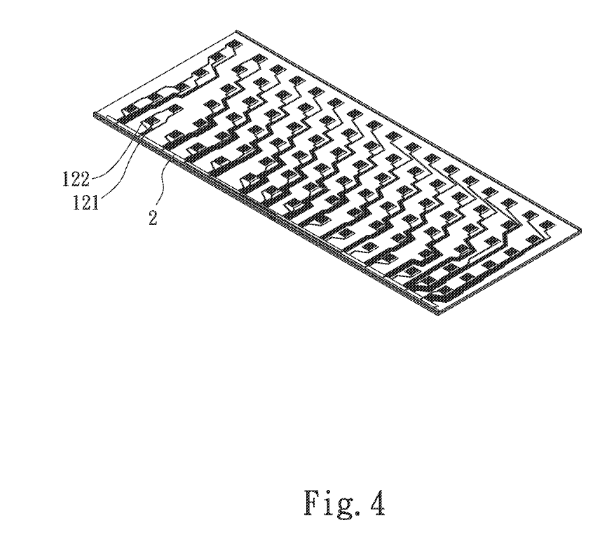

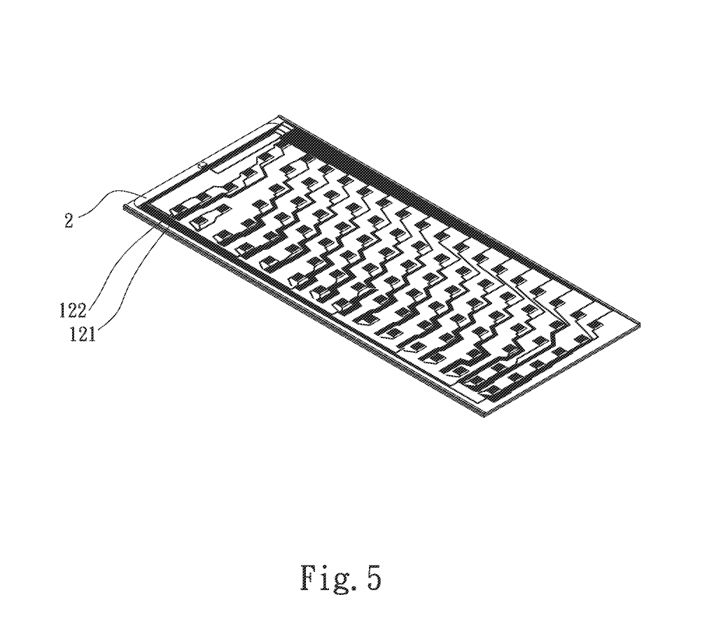

Please now refer to FIGS. 4 and 5. FIG. 4 is a perspective view of a second embodiment of the convenient portable input device of the present invention. FIG. 5 is another perspective view of the second embodiment of the convenient portable input device of the present invention. The second embodiment is partially identical to the first embodiment in structure and thus will not be repeatedly described hereinafter. The second embodiment is different from the first embodiment in that the second embodiment further includes a flexible circuit board 2. The flexible circuit board 2 is disposed on the long side of the flexible main body 11 (as shown in FIG. 4) or the short side of the flexible main body 11 (as shown in FIG. 5). The flexible circuit board 2 is electrically connected to the first and second sensing electrodes 121, 122. By means of the flexible circuit board 2, the portable input device 1 can be connected to other electronic devices and co-used therewith. Alternatively, by means of the flexible circuit board 2, the portable input device 1 can be connected to an external power supply (such as a mobile power) to obtain power.

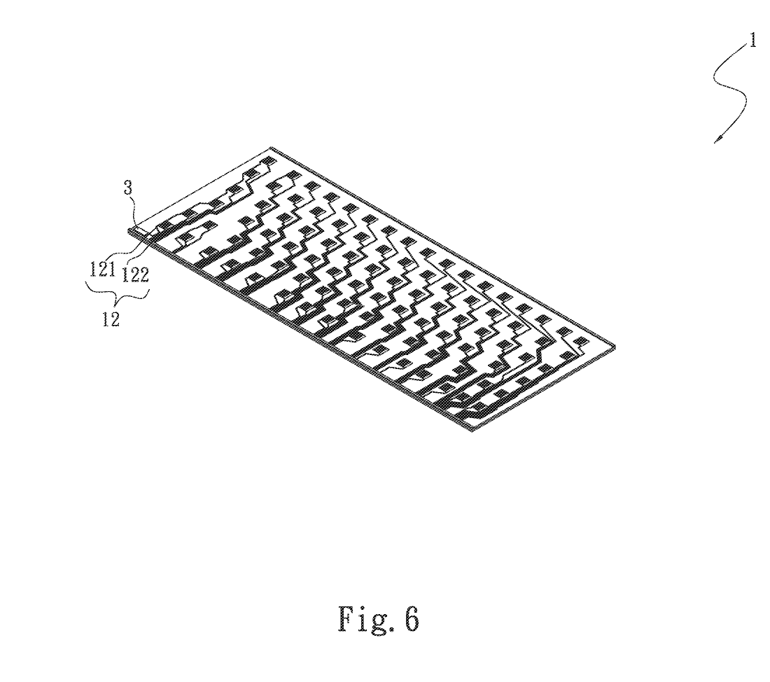

Please now refer to FIG. 6, which is a perspective view of a third embodiment of the convenient portable input device of the present invention. The third embodiment is partially identical to the first embodiment in structure and thus will not be repeatedly described hereinafter. The third embodiment is different from the first embodiment in that the third embodiment further includes a wireless signal transmission unit 3 electrically connected to the first and second sensing electrodes 121, 122. The wireless signal transmission unit 3 is selected from a group consisting of an infrared transmitter, a Bluetooth transmitter, an RF signal transmitter and an NCF transmission chip. By means of the wireless signal transmission unit 3, the portable input device 1 can be connected to other electronic devices and co-used therewith. Alternatively, by means of the wireless signal transmission unit 3, the portable input device 1 can obtain power via the electromagnetic wave in the wireless signal.

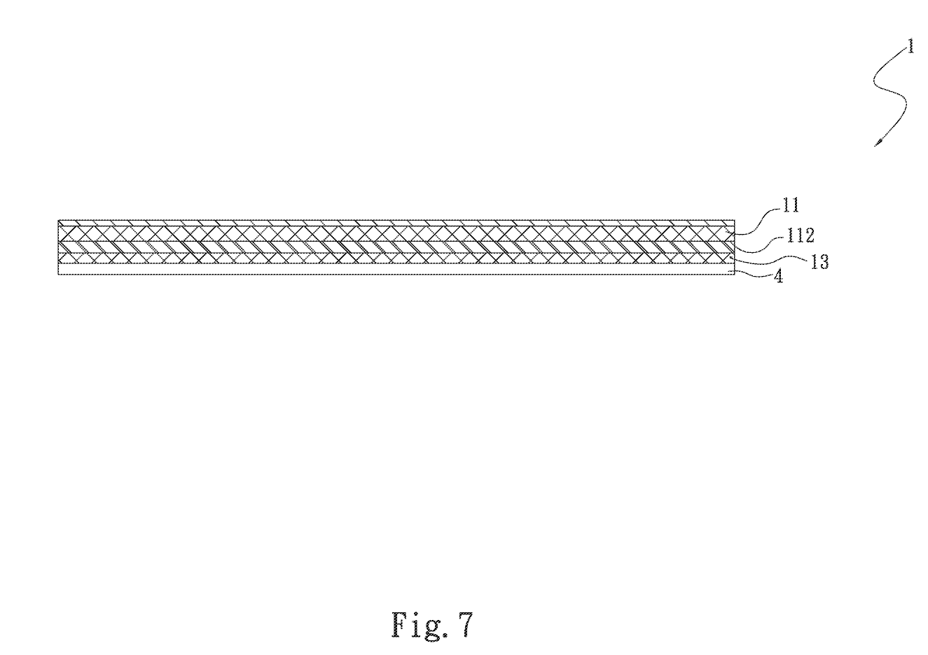

Please now refer to FIG. 7, which is a sectional view of a fourth embodiment of the portable input device of the present invention. The fourth embodiment is partially identical to the first embodiment in structure and thus will not be repeatedly described hereinafter. The fourth embodiment is different from the first embodiment in that an anti-inference layer 4 is disposed on the other face of the protection layer 13, which face is distal from the second face 112 of the flexible main body 11. The anti-interference layer 4 is an anti-EMI layer for preventing the portable input device 1 from interference and noise affection during signal transmission.

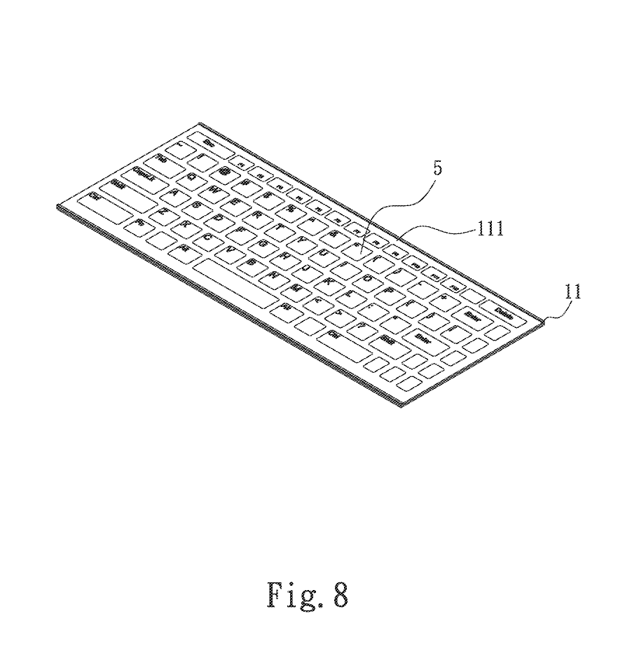

Please now refer to FIG. 8, which is a perspective view of a fifth embodiment of the portable input device of the present invention. The fifth embodiment is partially identical to the first embodiment in structure and thus will not be repeatedly described hereinafter. The fifth embodiment is different from the first embodiment in that the fifth embodiment further includes a graphic layer 5 formed on the first face 111 of the flexible main body 11 or one face of the protection layer 133 by means of printing, engraving or stamping. In this embodiment, the graphic layer 5 is disposed on, but not limited to, the first face 111 of the flexible main body 11 for illustration purposes only. The graphic layer 5 can create virtual keys or graphs or characters on the first face 111.

In the above embodiments, the flexible main body 11 of the portable input device 1 is made of polymer material selected from a group consisting of polyethylene terephthalate (PET), polycarbonate (PC), polyethylene (PE), polyvinyl chloride (PVC), polypropylene (PP), polystyrene (PS), polymethylmethacrylate (PMMA) and cyclo olefin copolymer (COC). The flexible main body 11 is flexible, lightweight and thin for a user to conveniently carry.

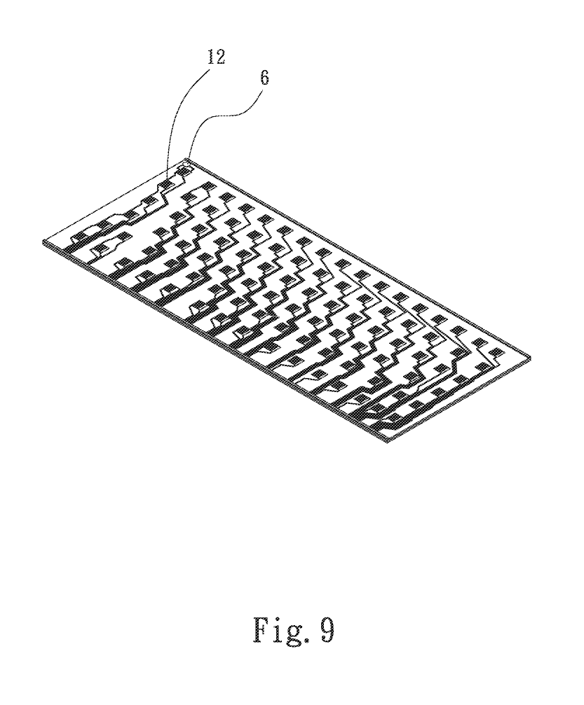

In the above embodiments, the portable input device 1 has both keyboard and handwriting tablet input functions. By means of a switch unit 6 (as shown in FIG. 9), a user can freely switch the portable input device 1 between a keyboard mode and a handwriting tablet mode. The switch unit 6 is a solid key or a slide switch. In FIG. 9, the switch unit 6 is, but not limited to, a solid key for illustration purposes only. The switch unit 6 is electrically connected to the sensing electrode layer 12.

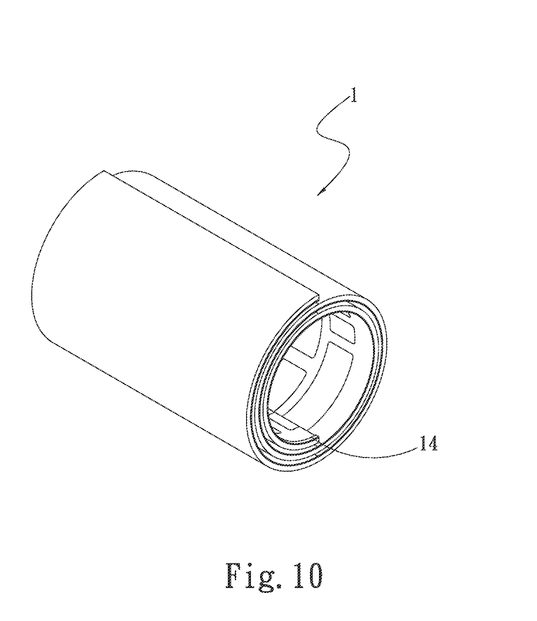

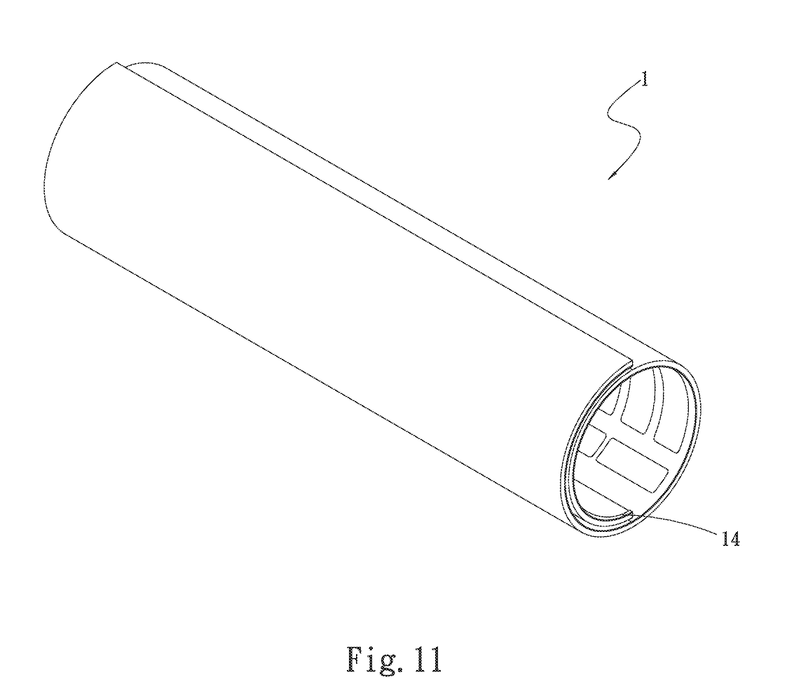

In use of the convenient portable input device 1 of the present invention, when the memory metal body 14 absorbs the heat of a user or the heat generated by the sensing electrode layer 12 in operation or receives internal or external current, the originally curled convenient portable input device 1 (as shown in FIGS. 10 and 11) is uncurled into a tablet form. When not used, due to the memory property of the memory metal body 14, the memory metal body 14 can restore the convenient portable input device 1 to the curled state for easy carry or storage.

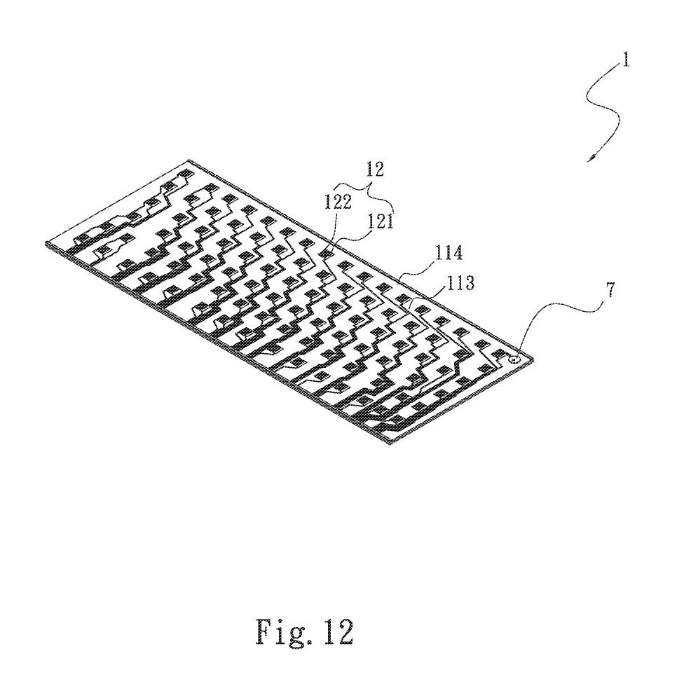

Please now refer to FIG. 12, which is a perspective view of a seventh embodiment of the portable input device of the present invention. The seventh embodiment is partially identical to the first embodiment in structure and thus will not be repeatedly described hereinafter. The seventh embodiment is different from the first embodiment in that a power supply 7 is disposed on the non-touch section 114 of the flexible main body 11 and electrically connected to the first and second sensing electrodes 121, 122. The power supply 7 is selected from a group consisting of rechargeable battery, replaceable cell, solar battery and bio-energy battery for supplying power for wireless input use.

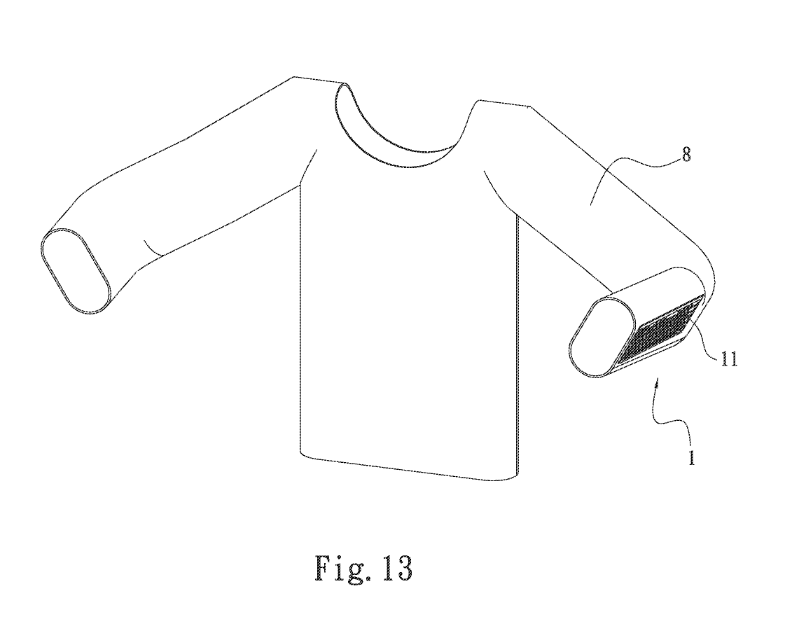

Please now refer to FIG. 13, which is a perspective view of an eighth embodiment of the portable input device of the present invention. The eighth embodiment is partially identical to the first embodiment in structure and thus will not be repeatedly described hereinafter. The eighth embodiment is different from the first embodiment in that the portable input device 1 can be connected to a texture 8. Alternatively, the flexible main body 11 can be directly formed on the texture 8 by means of polymer material. The texture 8 can be a dress or any other accessory. A wearer can use the portable input device 1 on the dress to input data.

The present invention has been described with the above embodiments thereof and it is understood that many changes and modifications in the above embodiments can be carried out without departing from the scope and the spirit of the invention that is intended to be limited only by the appended claims.

What is claimed is:

1. A convenient portable input device comprising:
a flexible main body having a first face and a second face;
a sensing electrode layer having a first sensing electrode and a second sensing electrode, the first and second sensing electrodes being arranged in alignment with each other without contacting each other, the sensing electrode layer being disposed on the second face of the flexible main body;
a protection layer correspondingly disposed on the second face of the flexible main body to cover the sensing electrode layer; and
a memory metal body disposed on one face of the flexible main body or one face of the protection layer.

2. The convenient portable input device as claimed in claim 1, wherein the flexible main body is defined with a touch section and a non-touch section arranged around the touch section, the first and second sensing electrodes of the sensing electrode layer being disposed in the touch section, the first and second sensing electrodes partially extending to the non-touch section.

3. The convenient portable input device as claimed in claim 1, further comprising a flexible circuit board, the flexible circuit board being electrically connected to the first and second sensing electrodes.

4. The convenient portable input device as claimed in claim 1, further comprising a wireless signal transmission unit electrically connected to the first and second sensing electrodes, the wireless signal transmission unit being selected from a group consisting of an infrared transmitter, a Bluetooth transmitter, an RF signal transmitter and an NCF transmission chip.

5. The convenient portable input device as claimed in claim 1, wherein an anti-inference layer is disposed on the other face of the protection layer, which face is distal from the second face of the flexible main body.

6. The convenient portable input device as claimed in claim 1, further comprising a graphic layer formed on the first face of the flexible main body or one face of the protection layer.

7. The convenient portable input device as claimed in claim 1, wherein the flexible main body is made of polymer material selected from a group consisting of polyethylene terephthalate (PET), polycarbonate (PC), polyethylene (PE), polyvinyl chloride (PVC), polypropylene (PP), polystyrene (PS), polymethylmethacrylate (PMMA) and cyclo olefin copolymer (COC).

8. The convenient portable input device as claimed in claim 1, further comprising a switch unit, which is a solid key or a slide switch.

9. The convenient portable input device as claimed in claim 1, wherein the memory metal body is selected from a group consisting of iron-based alloy, nickel-titanium alloy, copper-based alloy, zinc and aluminum.

10. The convenient portable input device as claimed in claim 1, wherein the flexible main body has a long side and a short side, the memory metal body being disposed along the long side of the flexible main body in parallel to the long side or disposed along the short side of the flexible main body in parallel to the short side.

11. The convenient portable input device as claimed in claim 1, further comprising a power supply disposed on the non-touch section of the flexible main body and electrically connected to the first and second sensing electrodes.
